(19) United States
(12) Patent Application Publication
(10) Pub. No.: US 2012/0024560 A1
(43) Pub. Date: Feb. 2, 2012

(54) CASE FOR ENCLOSING AND REMAINING ATTACHED TO A MOBILE COMMUNICATION DEVICE WITH APPLIED FABRIC

(76) Inventors: Ryan Hill Mongan, Orange, CA (US); Bryan Lee Hynecek, Redwood City, CA (US); David John Law, Seattle, WA (US); Jarret Weis, San Francisco, CA (US); David Chiawen Lean, San Francisco, CA (US)

(21) Appl. No.: 13/192,423

(22) Filed: Jul. 27, 2011

Related U.S. Application Data
(60) Provisional application No. 61/400,410, filed on Jul. 27, 2010.

(51) Int. Cl. H05K 5/00

(52) U.S. Cl. 174/50

(57) ABSTRACT

Cases for enclosing and remaining attached to a mobile communications device may include a semi-rigid shell and a fabric covering attached thereto. The cases may include a semi-rigid shell with a recessed portion for accepting a fabric covering and the fabric covering.

### RELATED APPLICATION

This application is a NONPROVISIONAL of, claims priority to, and incorporates by reference U.S. Provisional Patent Application 61/400410 filed 26 Jul. 2010.

### FIELD OF THE INVENTION

The present invention relates to a case for enclosing and remaining attached to a mobile communications device including a semi-rigid shell and a fabric covering attached thereto.

### BACKGROUND

Conventional cases for enclosing mobile communications devices are limited to plastic, rubber, or silicon materials that offer few customization possibilities for users of the cases.

### SUMMARY

A case for enclosing and remaining attached to a mobile communications device including a semi-rigid shell and a fabric covering attached thereto is herein provided. Exemplary cases may include a semi-rigid shell including a recessed portion for accepting a fabric covering and the fabric covering. The semi-rigid shell may be made from, for example, a plastic, a rubber, an elastomeric material, or some combination thereof.

In some embodiments, the recessed portion may be positioned on an outer surface of the case while in other embodiments the recessed portion may be positioned on an inner surface of the case. When the recessed portion is positioned on an inner surface of the case, the semi-rigid shell may be at least partially transparent or translucent and the fabric may be at least partially visible through the semi-rigid shell.

In some embodiments, the shell includes a side-piece and at least one of a top surface and/or bottom surface. The side piece and the top surface and/or bottom surface may include the recessed portion and the fabric covering.

The fabric covering may include a first surface and a second surface. The first surface may be adhered to the semi-rigid shell within the recessed portion so that the second surface is level with or below an unrecessed portion of the semi-rigid shell. The first surface of the fabric may adhered to the semi-rigid shell via, for example, a glue, a bonding agent, an in-mold application process, an ultrasonic welding process, and/or a vibration welding process.

On some occasions, the fabric covering may serve to protect an enclosed mobile communications device from damage. On other occasions, the fabric may serve a decorative purpose and may be customizable by a user of the case. At times, the fabric may be capable of receiving at least one of a printed design and a pressure sensitive decal.

In some embodiments, the case may be customized to accommodate a particular type of mobile communication device. For example, the case may include one or more features or apertures that are aligned within the case to accommodate a feature or functionality of the enclosed mobile communication device. Exemplary apertures may be designed to accommodate a button, a camera, a light source, a microphone, a user interface, a power switch, and/or a power input port of an enclosed mobile communications device.

### BRIEF DESCRIPTION OF THE DRAWINGS

The present application is illustrated by way of example, and not limitation, in the figures of the accompanying drawings, in which:

FIG. 1A is a top view of an exemplary case in accordance with embodiments of the present invention;

FIG. 1B is a side view of an exemplary case in accordance with embodiments of the present invention;

FIGS. 1C is a cross-sectional view of an exemplary case in accordance with embodiments of the present invention;

FIG. 2 is a top view of an exemplary fabric covering in accordance with embodiments of the present invention;

FIG. 3A is a top view of an exemplary case with applied fabric in accordance with embodiments of the present invention;

FIG. 3B is a side view of an exemplary case with applied fabric in accordance with embodiments of the present invention;

FIGS. 3C is a cross-sectional view of an exemplary case with applied fabric in accordance with embodiments of the present invention;

FIGS. 4A and 4B illustrate exemplary mobile communication devices enclosed within a case in accordance with embodiments of the present invention;

FIG. 5A is a top view of an exemplary case with applied fabric and an aperture in accordance with embodiments of the present invention; and

FIG. 5B is a top view of an exemplary mobile communication device enclosed within an exemplary case with applied fabric and an aperture in accordance with embodiments of the present invention.

Throughout the drawings, the same reference numerals and characters, unless otherwise stated, are used to denote like features, elements, components, or portions of the illustrated embodiments. Moreover, while the subject invention will now be described in detail with reference to the drawings, the description is done in connection with the illustrative embodiments. It is intended that changes and modifications can be made to the described embodiments without departing from the true scope and spirit of the subject invention as defined by the appended claims.

### DETAILED DESCRIPTION

At times, it may be desirable to apply fabric to a case for enclosing and remaining attached to a mobile communications device, such as a mobile telephone, a hinged laptop computer, and a tablet computer. The applied fabric may serve to increase the durability and/or flexibility of the case and may also improve the protection provided by the case to an enclosed mobile communications device. The applied fabric may also serve to increase visual and/or tactile appeal of a case to a user without increasing the overall cost of manufacturing the case.

Application of fabric to a case may also increase customization options available for a user of the case at least because a great variety of fabric and/or underlying semi-rigid shell options may be provided to the user. In some embodiments, a fabric covering and an underlying semi-rigid shell may be selected as individual components of a case that may be independently provided by a user and then combined together by, for example, the user and/or a manufacturer of the case, to create a customized case.

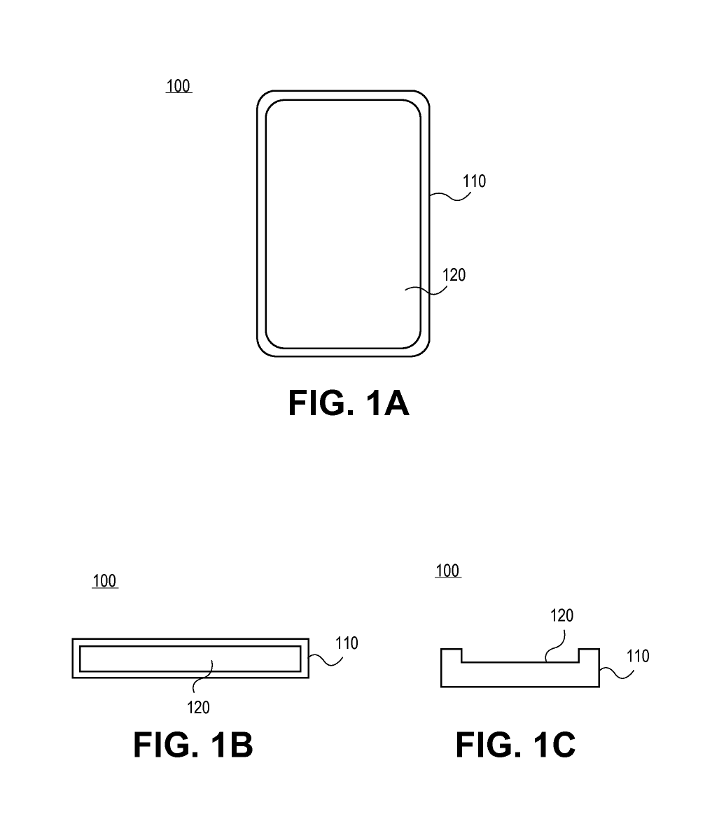

FIG. 1A is a top view of a case 100 for enclosing and remaining attached to a mobile communications device including a semi-rigid shell 110 and a recessed portion 120 for accepting a fabric covering. Semi-rigid shell 110 may be fabricated from, for example, a plastic material, a rubber material, an elastomeric material, a metal, and/or some combination thereof and may be any color or texture.

Recessed portion 120 may be any size and/or shape and may be sized so as to accept a fabric covering. On some occasions, recessed portion 120 may be shallow relative to the overall thickness of the semi-rigid shell (e.g., a few millimeters) but this is not necessarily the case. In some embodiments, recessed portion 120 may be positioned on an outer surface of semi-rigid shell 110, while in other embodiments, recessed portion 120 may positioned on an inner surface of semi-rigid shell 110.

FIG. 1B is a side view of case 100 including semi-rigid shell 110 and recessed portion 120 for accepting a fabric covering.

FIG. 1C is a cross-sectional view of case 100 including semi-rigid shell 110 and recessed portion 120 for accepting a fabric covering.

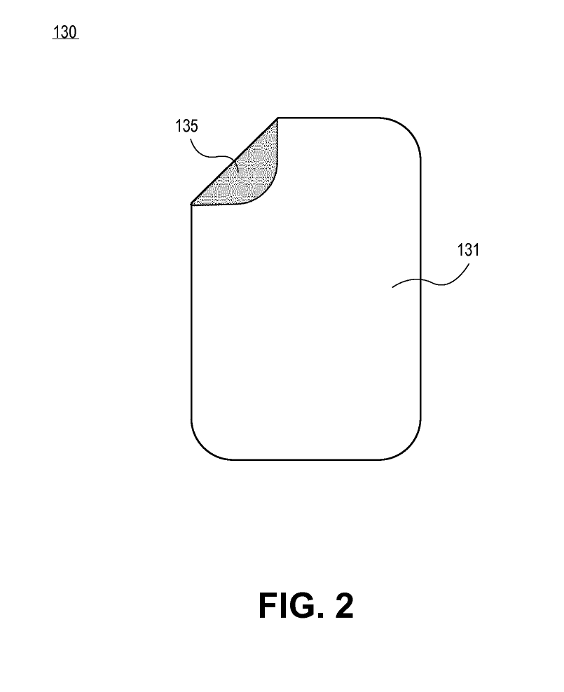

FIG. 2 is a top view of fabric 130 including a first surface 131 and a second surface 135. Fabric 130 may comprise, for example, cloth, plastic, paper, hemp, Tyvek™, or any combination thereof. On some occasions, fabric 130 may be capable of receiving, for example, a printed design or a pressure sensitive decal. On other occasions, fabric 130 may be customizable by a user of case 100, such that the user may select a particular fabric 130 from a variety of available fabrics 130 to apply to semi-rigid shell 110 within the recessed portion 120.

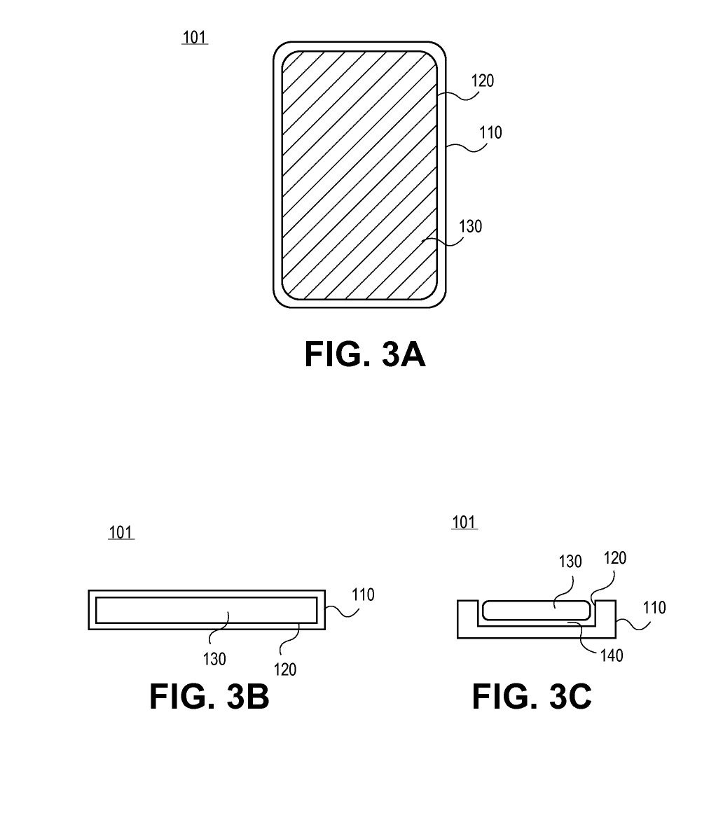

FIG. 3A is a top view of a case 101 with applied fabric 130 for enclosing and remaining attached to a mobile communications device. Case 101 includes semi-rigid shell 110 and fabric 130 adhered within recessed portion 120. In some embodiments, first surface 131 of fabric 130 may be adhered to semi-rigid shell 110 within recessed portion 120 via, for example, a glue, a bonding agent, an in-mold application process, an ultrasonic welding process, and a vibration welding process such that second surface 135 of fabric 130 is level with, or below, an unrecessed portion of semi-rigid shell 120. Positioning the second surface 135 in this manner may prevent removal of fabric 130 from semi-rigid shell 110 via peeling, fraying, or other unintentional means.

In some embodiments, recessed portion 120 may be positioned on an underside of case 100 and semi-rigid shell 130 may be at least partially transparent or translucent such that fabric 130, or a pattern included thereon, is at least partially visible through semi-rigid shell 110.

Application of fabric 130 to case 101 may serve many purposes, such as, but not limited to, protecting an enclosed mobile communications device from damage from, for example, shock, heat, water, and/or scratches, providing a decoration to case 101, providing a desired tactile experience to a user when holding case 101, and enhancing the flexibility and/or durability of case 101.

FIG. 3B is a side view of case 101 including semi-rigid shell 110, recessed portion 120, and fabric 130.

FIG. 3C is a cross-sectional view of case 101 including semi-rigid shell 110, recessed portion 120, fabric 130, and an optional adhesion layer 140. Optional adhesion layer 140 may be present in case 101 when, for example, a glue or other adhesive is used to adhere fabric 130 to case 101.

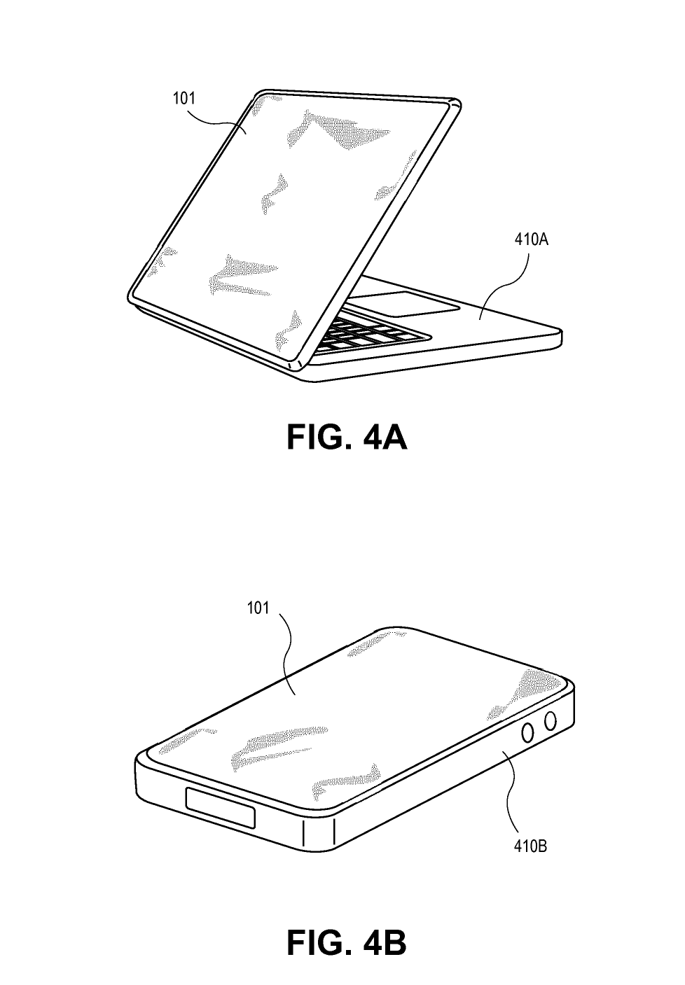

FIGS. 4A and 4B illustrate two the exemplary mobile communication devices enclosed within case 101. FIG. 4A illustrates an embodiment wherein a hinged laptop mobile communication device 410A is enclosed within case 101 and FIG. 4B illustrates an embodiment wherein a tablet computer and/or mobile telecommunication device 410B is enclosed within case 101.

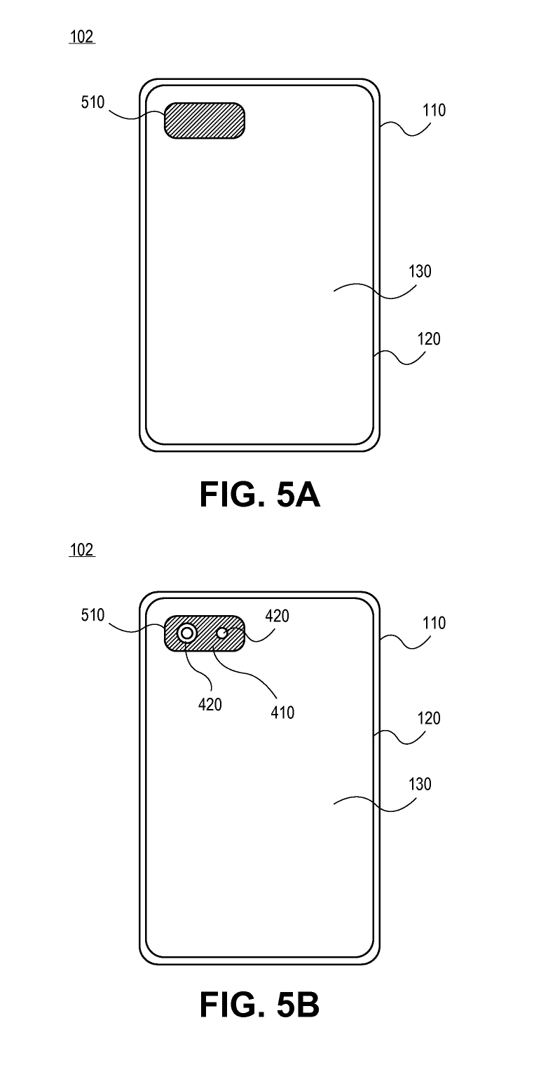

On some occasions, case 100 and/or 101 may be customized to accommodate a particular type of mobile communication device. On these occasions, case 100 and/or 101 may include an aperture or other feature sized and positioned to accommodate a feature of an enclosed mobile communication device. Such a feature is shown in FIG. 5A. FIG. 5A depicts a top view of a case 102 for enclosing and remaining attached to a mobile communications device including semi-rigid shell 110, fabric 130 adhered within recessed portion 120, and an aperture 510 sized and positioned to accommodate a feature of an enclosed mobile communication device.

FIG. 5B depicts a top view of a case 102 including semi-rigid shell 110, fabric 130 adhered within recessed portion 120, aperture 510, and underlying features 420 of mobile communication device 410. Exemplary underlying features 420 include a camera lens, a light source, a microphone, a user interface, a power switch, and a power input port.

Thus, cases for enclosing mobile communications devices with fabric applied thereto have been herein disclosed.

What is claimed is:

1. A case for enclosing and remaining attached to a mobile communications device comprising:
a semi-rigid shell including a recessed portion for accepting a fabric covering; and
the fabric covering including a first surface and a second surface, the first surface being adhered to the semi-rigid shell within the recessed portion, the second surface being level with or below an unrecessed portion of the semi-rigid shell.

2. The case of claim 1, wherein the case is customized to accommodate a particular type of mobile communication device.

3. The case of claim 1, wherein the case includes at least one aperture aligned within the case to accommodate a feature of the enclosed mobile communication device.

4. The case of claim 1, wherein a material comprising the semi-rigid shell is at least one of a plastic, a rubber, and an elastomeric material.

5. The case of claim 1, wherein the recessed portion is positioned on an outer surface of the case.

6. The case of claim 1, wherein the semi-rigid shell is at least partially transparent, the recessed portion is positioned on an inner surface of the case, and the fabric is at least partially visible through the semi-rigid shell.

7. The case of claim 1, wherein the first surface of the fabric is adhered to the semi-rigid shell via at least one of a glue, a bonding agent, an in-mold application process, an ultrasonic welding process, and a vibration welding process.

8. The case of claim 1, wherein the fabric covering serves to protect the enclosed mobile communications device from damage.

9. The case of claim 1, wherein the fabric serves a decorative purpose.

10. The case of claim 1, wherein the fabric is customizable by a user of the case.

11. The case of claim 1, wherein the fabric is capable of receiving at least one of a printed design and a pressure sensitive decal.

12. The case of claim 1, wherein the semi-rigid shell includes a side-piece and at least one of a top surface and a bottom surface and the at least one side piece and the at least one top surface and bottom surface include the recessed portion and the fabric covering.
